(19) United States
(12) Patent Application Publication
(10) Pub. No.: US 2013/0330925 A1
(43) Pub. Date: Dec. 12, 2013

(54) METHODS OF TREATING A DEVICE-SUBSTRATE AND SUPPORT-SUBSTRATES USED THEREIN

(71) Applicant: SAMSUNG ELECTRONICS CO., LTD., Suwon-si (KR)

(72) Inventors: Tae Hong MIN, Yongin-si (KR); CHAJEA JO, Bucheon-si (KR); Taeje CHO, Hwaseong-si (KR); YOUNG KUN JEE, Suwon-si (KR)

(73) Assignee: Samsung Electronics Co., Ltd., Suwon-si (KR)

(21) Appl. No.: 13/893,449

(22) Filed: May 14, 2013

(30) Foreign Application Priority Data
Jun. 7, 2012 (KR) 10-2012-0061125

(51) Int. Cl. H01L 21/768

(52) U.S. Cl. CPC H01L 21/76877
USPC 438/667

(57) ABSTRACT

Disclosed are methods of treating a device-substrate, and support-substrates used therein. The methods may include providing the device-substrate having an integrated circuit, bonding a first top surface of the device-substrate to a support-substrate, and polishing a first bottom surface of the device-substrate. The support-substrates include a second top surface, a second bottom surface opposite to the second top surface, and a sidewall connecting the second top and bottom surfaces. Additionally, the support-substrates further include a grooved portion spaced apart from the sidewall and blocking a crack in the support-substrates occurring from the sidewall.

### CROSS-REFERENCE TO RELATED APPLICATIONS

This U.S. non-provisional patent application claims priority under 35 U.S.C. §119 to Korean Patent Application No. 10-2012-0061125, filed on Jun. 7, 2012, the entirety of which is incorporated by reference herein.

### BACKGROUND OF THE INVENTION

1. Field of the Invention

The present general inventive concept relates to methods of treating a device-substrate and support-substrates used therein and, more particularly, to methods of treating a device-substrate including a process of thinning a device-substrate, and also to support-substrates used in the methods.

2. Description of the Related Art

Electronic devices such as mobile phones, digital display devices, and integrated circuit (IC) cards may include high-capacity semiconductor devices. Thinness, small size, and lightness of the semiconductor devices have been demanded. The semiconductor devices may include semiconductor packages such as a chip size package (CSP), and a multi chip package (MCP) including stacked semiconductor chips. The semiconductor devices may be thinned by a polishing process or an etching process. A thinning process for thinning the semiconductor devices may be performed on a wafer including the semiconductor devices.

### SUMMARY OF THE INVENTION

Features and utilities of the present general inventive concept may provide methods of treating a device-substrate capable of minimizing a crack and support-substrates used therein.

Features and utilities of the present general inventive concept may also provide methods of treating a device-substrate to prevent the device-substrate from being broken, and support-substrates used therein.

Additional features and utilities of the present general inventive concept will be set forth in part in the description which follows and, in part, will be obvious from the description, or may be learned by practice of the general inventive concept.

Embodiments of the present general inventive concept may also provide methods of treating a device-substrate to prevent the device-substrate from being broken, and support-substrates used therein.

According to an exemplary embodiment of the present general inventive concept, a method of treating a device-substrate may include: providing the device-substrate having an integrated circuit; bonding a first top surface of the device-substrate to a support-substrate; and polishing a first bottom surface of the device-substrate. The support-substrate may include a second top surface, a second bottom surface opposite to the second top surface, and a sidewall connecting the second top and bottom surfaces; the support-substrate may include a grooved portion spaced apart from the sidewall and blocking a crack occurring from the sidewall.

The grooved portion may include a first groove formed in the second top surface and a second groove formed in the second bottom surface; and the second groove may be spaced apart from the first groove.

A depth of the first groove may be greater than a depth of the second groove.

An area of the first top surface of the device-substrate may be substantially equal to an area of the second top surface of the support-substrate.

The grooved portion may have a ring-shape in a plan view.

The grooved portion may have a toothed wheel-shape in a plan view.

The sidewall of the support-substrate may have a concave-convex part.

The method may further include: forming a via-hole in the device-substrate extending from the first top surface toward the first bottom surface of the device-substrate; and forming a via-electrode in the via-hole.

The method may further include: after polishing the first bottom surface, etching the polished first bottom surface to expose the via-electrode.

According to another exemplary embodiment of the present general inventive concept, a support-substrate may include: a top surface; a bottom surface opposite to the top surface; a sidewall connecting the top and bottom surfaces; and a grooved portion spaced apart from the sidewall and blocking a crack in the support-substrate occurring from the sidewall.

The grooved portion may include a first groove formed in the top surface; and a second groove formed in the bottom surface and spaced apart from the second groove.

A depth of the first groove may be greater than a depth of the second groove.

The grooved portion may have a ring-shape in a plan view.

The grooved portion may have a toothed wheel-shape in a plan view.

The sidewall may have a concave-convex part.

In the method of treating a device-substrate, an area of the first bottom surface of the device substrate may be less than an area of the first top surface of the device substrate.

In the method of treating a device-substrate, the first and second grooves may have different shapes.

According to another exemplary embodiment of the present general inventive concept, a method of treating a device-substrate may include: providing a support-substrate having a grooved portion, the grooved portion being configured to block a crack in the support-substrate occurring from a sidewall of the support-substrate; bonding the support-substrate to a first surface of the device-substrate; and polishing a second surface of the device-substrate, the second surface being opposite to the first surface.

According to another exemplary embodiment of the present general inventive concept, a support-substrate may include: a first surface; a second surface opposite the first surface; a sidewall connecting the first and second surfaces; and a grooved portion formed in at least the first or second surface, the grooved portion being configured to block a crack in the support-substrate occurring from the sidewall.

### BRIEF DESCRIPTION OF THE DRAWINGS

These and/or other features and utilities of the present general inventive concept will become apparent and more readily appreciated from the following description of the embodiments, taken in conjunction with the accompanying drawings of which:

FIG. 1 is a flowchart illustrating a method of treating a device-substrate according to exemplary embodiments of the present general inventive concept;

FIGS. 2 to 11 are cross-sectional views illustrating the method described in FIG. 1;

FIG. 12 is a plan view illustrating a general support-substrate in which a crack occurs;

FIG. 13 is a plan view illustrating a support-substrate described in FIGS. 5 to 11;

FIG. 14 is a perspective view illustrating a support-substrate according to a first exemplary embodiment of the present general inventive concept;

FIG. 15 is a cross-sectional view taken along a line I-I′ of FIG. 14;

FIG. 16 is a perspective view illustrating a support-substrate according to a second exemplary embodiment of the present general inventive concept; and

FIG. 17 is a perspective view illustrating a support-substrate according to a third exemplary embodiment of the present general inventive concept.

### DETAILED DESCRIPTION OF THE PREFERRED EMBODIMENTS

The present general inventive concept will now be described more fully hereinafter with reference to the accompanying drawings, in which exemplary embodiments of the present general inventive concept are shown and like reference numerals refer to like elements throughout. The embodiments are described below in order to explain the present general inventive concept while referring to the figures. The advantages and features of the present general inventive concept and methods of achieving them will be apparent from the following exemplary embodiments that will be described in more detail with reference to the accompanying drawings. It should be noted, however, that the present general inventive concept is not limited to the following exemplary embodiments, and may be implemented in various forms. Accordingly, the exemplary embodiments are provided only to disclose the present general inventive concept and let those skilled in the art know the category of the present general inventive concept. In the drawings, embodiments of the present general inventive concept are not limited to the specific examples provided herein and details are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes,” and “including”, when used herein, specify the presence of stated features, integers, steps, operations, elements, and/or components, but do not preclude the presence or addition of one or more other features, integers, steps, operations, elements, components, and/or groups thereof.

Additionally, the embodiments described herein will be described with reference to sectional views described in the Figures as ideal exemplary views of the present general inventive concept. Accordingly, shapes of the exemplary views may be modified according to manufacturing techniques and/or allowable errors. Therefore, the exemplary embodiments of the present general inventive concept are not limited to the specific shapes illustrated in the Figures, but may include other shapes that may be created according to manufacturing processes. Areas exemplified in the Figures have general properties, and are used to illustrate specific shapes of elements. Thus, the Figures should not be construed as limiting the scope of the present general inventive concept.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present general inventive concept explained and illustrated herein include their complementary counterparts.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features when manufactured. Thus, the regions illustrated in the figures are schematic in nature and their shapes are not intended to illustrate the actual shape of a region of a device and are not intended to limit the scope of exemplary embodiments.

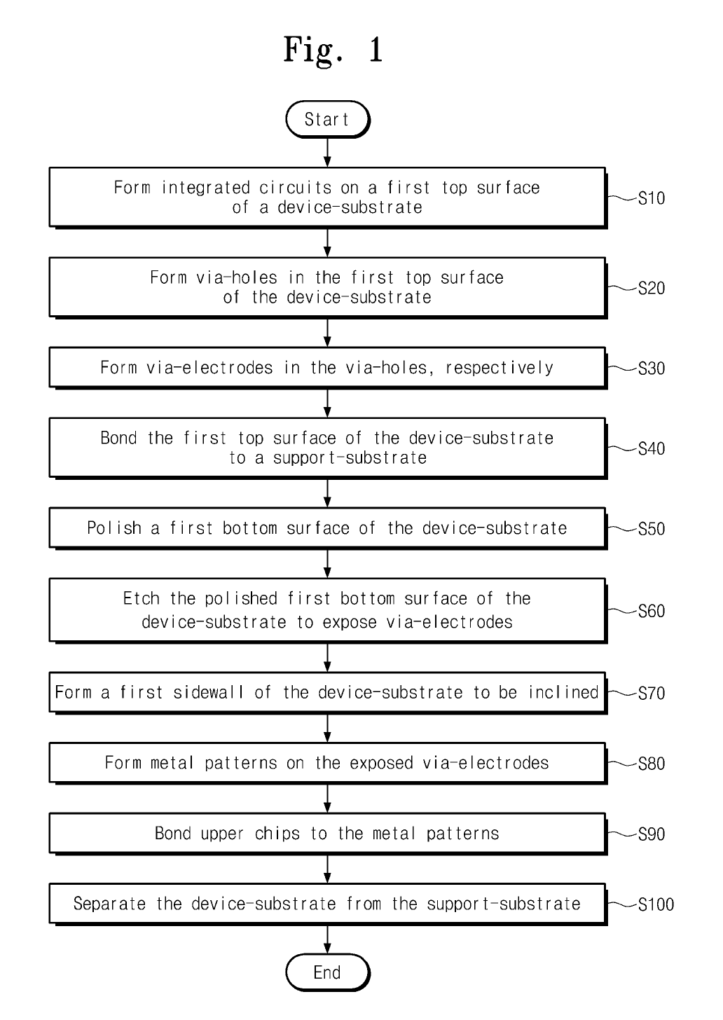

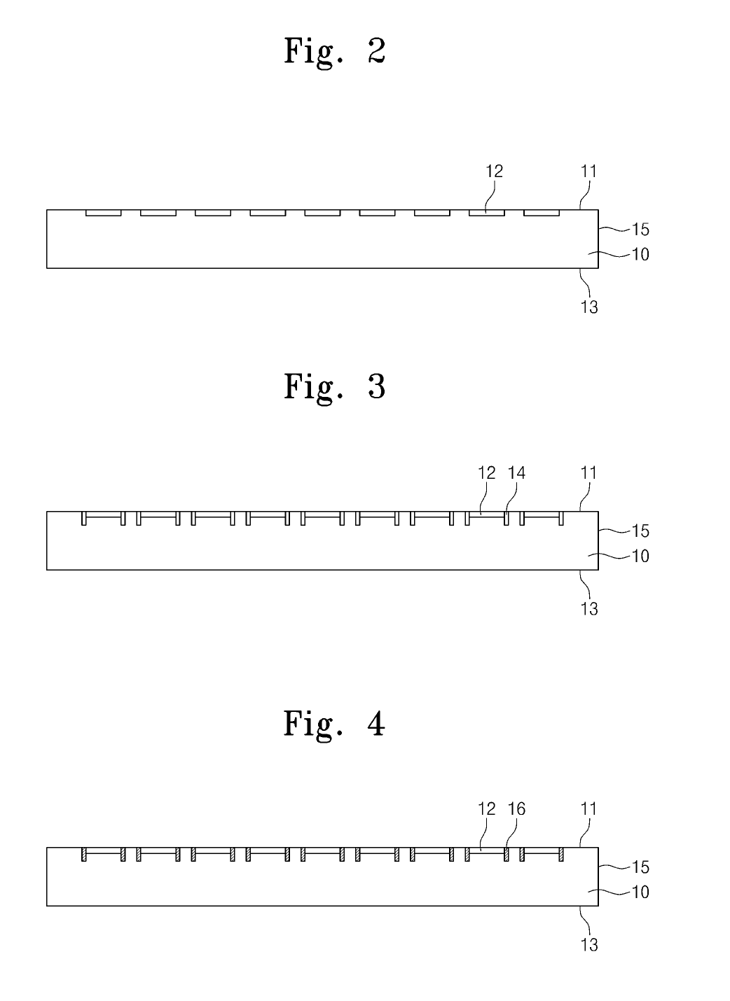

FIG. 1 is a flowchart illustrating a method of treating a device-substrate according to exemplary embodiments of the present general inventive concept. FIGS. 2 to 11 are cross-sectional views illustrating the method described in FIG. 1.

Referring to FIGS. 1 and 2, integrated circuits 12 are formed on a first top surface 11 of a device-substrate 10 (operation S10). The device-substrate 10 may include the first top surface 11, a first bottom surface 13 opposite to the first top surface 11, and a first sidewall 15 connecting the first top and bottom surfaces 11 and 13. The device-substrate 10 may be a silicon wafer of a circular shape having a diameter of about 30 cm. The integrated circuits 12 may include a micro processor, a memory device, and/or a sensor. The integrated circuits 12 may be formed by a photolithography process, an ion implantation process, an etching process, a deposition process, and/or a cleaning process. Each of the integrated circuits 12 may be formed to a predetermined depth from the first top surface 11. The predetermined depth may be within a range of about 10 μm to about 100 μm. Even though not shown in the drawings, each of the integrated circuits 12 may include dopant regions, thin film patterns, and/or interlayer insulating layers. The dopant regions may include a first conductive type dopant region doped with dopants of a first conductivity type such as donors, and a second conductivity type dopant region doped with dopants of a second conductivity type such as acceptors. The thin film patterns may include a gate electrode, a gate insulating layer, a floating gate, a pad electrode, a spacer, a resistor layer, a dielectric layer, a storage electrode, a common electrode, a metal interconnection, a contact plug, and/or a fuse. The interlayer insulating layer may include a silicon oxide layer and/or a silicon nitride layer.

Referring to FIGS. 1 and 3, via-holes 14 are formed in the first top surface 11 of the device-substrate 10 (operation S20). The via-hole 14 may be formed to be adjacent to the integrated circuit 12. The via-hole 14 may be formed by a dry etching process. For example, the via-hole 14 may have a depth within a range of about 120 μm to about 150 μm from the first top surface 11 of the device-substrate 10.

Referring to FIGS. 1 and 4, a via-electrode 16 is formed in a via-hole 14 (operation S30). The via-electrode 16 may be electrically connected to the integrated circuit 12. The via-electrode 16 may include a metal having high conductibility. For example, the via-electrode 16 may include at least one of tungsten, aluminum, tantalum, and/or copper. The via-electrode 16 may be formed by a metal deposition process and a planarization process. The metal deposition process may include a sputtering process and/or a chemical vapor deposition process. The planarization process may include a chemical mechanical polishing (CMP) process and/or a dry etching process. Due to the shape of the via-hole 14, a bottom surface of the via-electrode 16 may be disposed at a depth within a range of about 120 μm to about 150 μm from the first top surface 11 of the device-substrate 10.

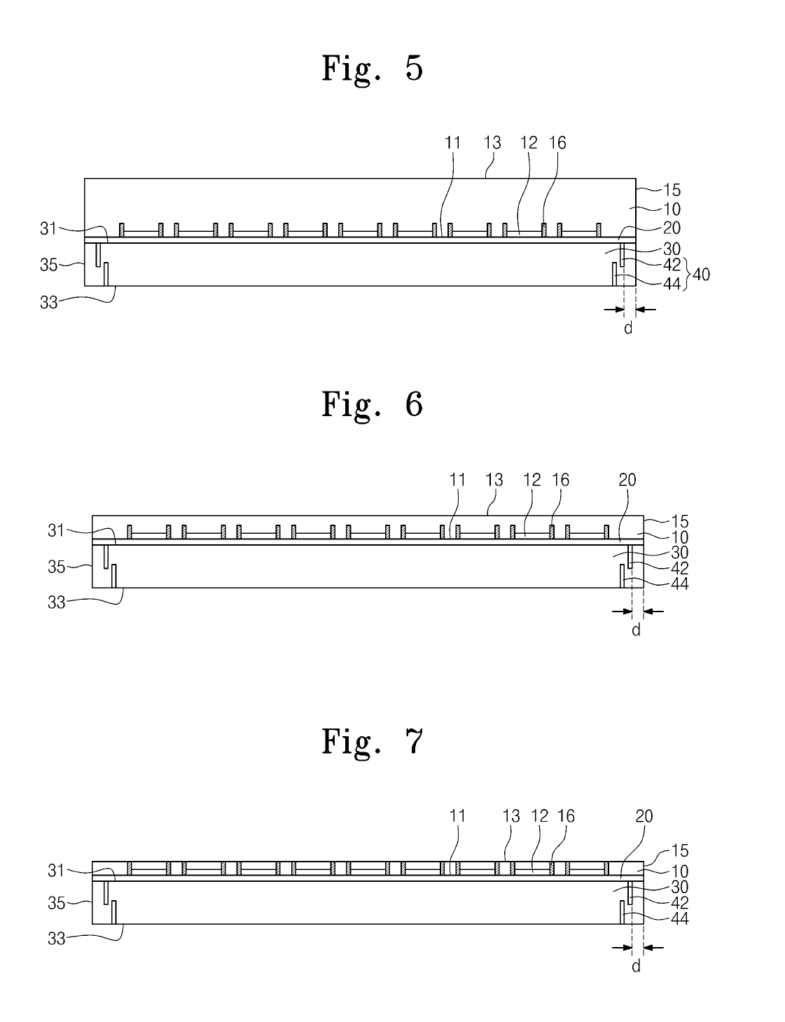

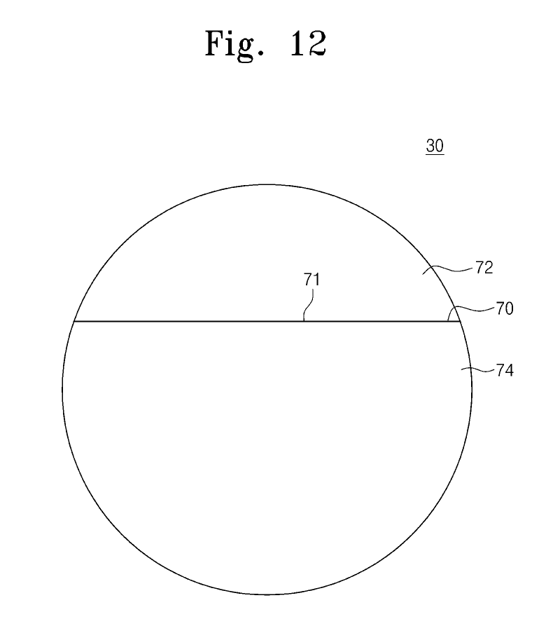

Referring to FIGS. 1 and 5, the first top surface 11 of the device-substrate 10 is bonded to a support-substrate 30 (operation S40). The device-substrate 10 may be bonded to the support-substrate 30 by an adhesive layer 20. The adhesive layer 20 may include a synthetic resin-based organic adhesive or a natural resin-based organic adhesive. The synthetic resin-based organic adhesive may include epoxy, styrene, and/or phenol. The natural resin-based organic adhesive may include rubber, glue, and/or resin. The support-substrate 30 may be a bare silicon wafer having the same size as the device-substrate 10. The bare silicon wafer may have a crystal plane 71 (illustrated in FIG. 12). The support-substrate 30 may have a second top surface 31, a second bottom surface 33 opposite to the second top surface 31, and a second sidewall 35 connecting the second top and bottom surfaces 31 and 33. The support-substrate 30 may include at least one grooved portion 40 spaced apart from the second sidewall 35 by a distance d. The grooved portion 40 may include a first groove 42 formed at the second top surface 31 and a second groove 44 formed at the second bottom surface 33. The second groove 44 may be spaced apart from the first groove 42, such that the first groove 42 is spaced apart from the second sidewall 35 by a first distance and the second groove 44 is space apart from the second sidewall by a second distance. The first groove 42 may extend from the second top surface 31 toward the second bottom surface 33. The second groove 44 may extend from the second bottom surface 33 toward the second top surface 31. A depth of the first groove 42 may be greater than a depth of the second groove.

Referring to FIGS. 1 and 6, the first bottom surface 13 of the device-substrate 10 is polished (operation S50). The first bottom surface 13 of the device-substrate 10 may be polished by a chemical mechanical polishing (CMP) process. The device-substrate 10 may be thinned to have a thickness within a range of about 150 μm to about 200 μm by operation S50. The device-substrate 10 may be fixed on a CMP apparatus (not shown) by the support-substrate 30.

Referring to FIGS. 1 and 7, the polished first bottom surface 13 of the device-substrate 10 is etched to expose the via-electrodes 16 (operation S60) after operation S50. The first bottom surface 13 may be etched by a dry etching process in operation S60. The dry etching process may not damage the exposed via-electrodes 16 at the first bottom surface 13. The device-substrate 10 may be thinned to have a thickness within a range of about 70 μm to about 150 μm by operation S60.

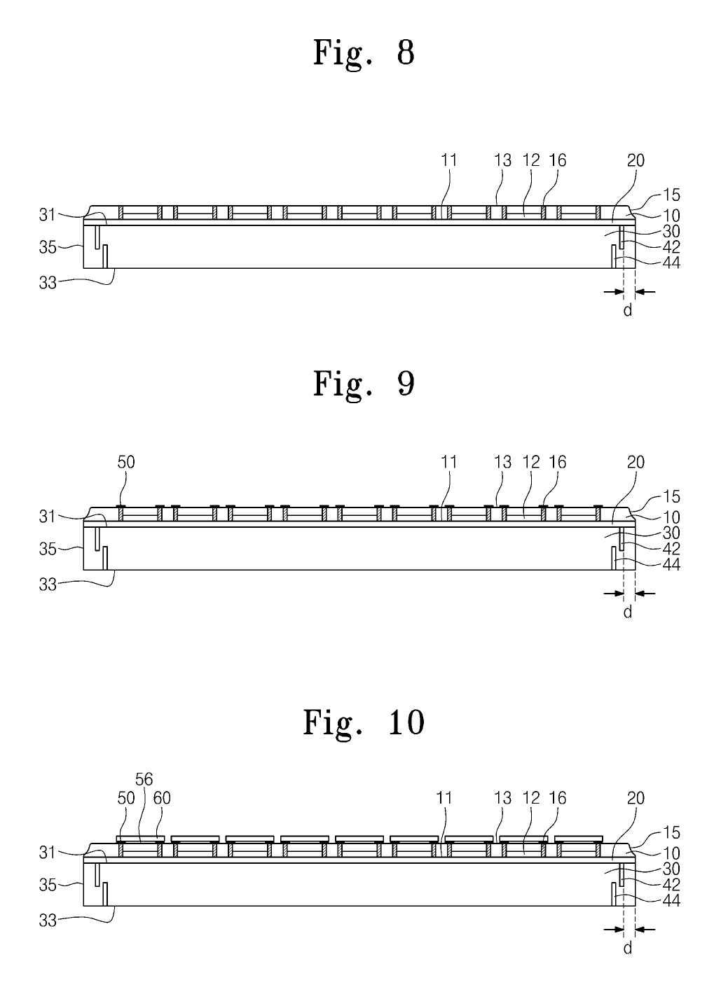

Referring to FIGS. 1 and 8, the first sidewall 15 may be formed to be inclined from the first bottom surface 13 to the first top surface 11 (operation S70). An area of the first bottom surface 13 may become reduced by the inclined first sidewall 15. The area of the first bottom surface 13 may therefore be smaller than that of the first top surface 11. The device-substrate 10 may be polished by a grinder (not shown). The inclined first sidewall 15 may decrease breakage of the device-substrate 10 which is caused by an external impact.

Referring to FIGS. 1 and 9, metal patterns 50 are formed on the exposed via-electrodes 16 (operation S80). The metal patterns 50 may include pads (not shown) and/or bumps (not shown). The pads may be formed by a metal deposition process and a patterning process. The patterning process may include a photolithography process and an etching process. The bumps may be bonded to the pads by a first bonding apparatus (not shown) and/or a printed apparatus (not shown). The bumps may include solder balls (not shown).

Referring to FIGS. 1 and 10, upper chips 60 are bonded to the metal patterns 50 (operation S90). The upper chips 60 may be connected to the integrated circuits 12 in one-to-one correspondence. The upper chips 60 may be bonded to the first bottom surface 13 of the device-substrate 10 by a flip chip bonder (not shown). The upper chips 60 may be electrically connected to the integrated circuits 12 through the via-electrodes 16 and the metal patterns 50. A sealant 56 may fill a space between the upper chips 60 and the device-substrate 10. The sealant 56 may protect the metal patterns 50.

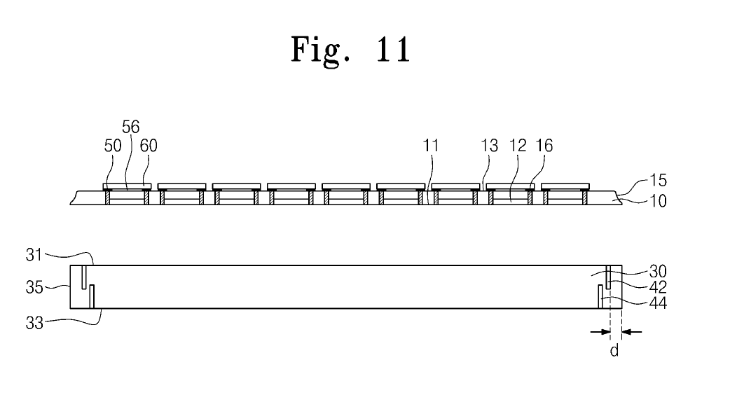

Referring to FIGS. 1 and 11, the device-substrate 10 is separated from the support-substrate 30 (operation S100). The adhesive layer 20 between the device-substrate 10 and the support-substrate 30 may be removed by an organic solvent. The device-substrate 10 and the support-substrate 30 may be soaked in the organic solvent. The organic solvent may include at least one of ethyl alcohol, methyl alcohol, butanol, and acetone.

Even though not shown in the drawings, after the device-substrate 10 is separated from the support-substrate 30, the device-substrate 10 may be divided into stack structures by a sawing process and/or a dicing process. Each of the stack structures may include a lower chip (not shown) and the upper chip 60 which are sequentially stacked. The lower chip may include the integrated circuit 12. The lower chip may have a size similar to that of the upper chip 60.

After operation S100, the support-substrate 30 may be reused for flat fixing another device substrate according to the same order of operations described above with reference to FIGS. 1-11. The support-substrate 30 may increase stability in manufacturing processes from the process polishing the device-substrate 30 to the process bonding the upper chips 60 to the device-substrate 30. The support-substrate 30 may fix the device-substrate 10 in semiconductor manufacturing apparatuses (not shown) such as a CMP apparatus, an etching apparatus, a photolithography apparatus, an exposure apparatus, a cleaning apparatus, a bump bonding apparatus, and/or a flip chip bonding apparatus. The support-substrate 30 may be transferred into the semiconductor manufacturing apparatuses by transfer apparatuses (not shown) such as a conveyor or a carrier. The support-substrate 30 may also increase ease of movement of the device-substrate 10 between the semiconductor manufacturing apparatuses. Thus, the support-substrate 30 may increase productivity of manufacturing semiconductor devices. However, the support-substrate 30 may be broken in the semiconductor manufacturing apparatuses and/or transfer apparatuses by an external impact.

Referring to FIG. 12, the support-substrate 30 may be broken by a crack 70 caused by an external impact. The crack 70 may proceed along a crystal orientation of the support-substrate 30. Specifically, the crack 70 may occur from a sidewall of the support-substrate 30 along a crystal plane 71 of silicon crystals making up the support-substrate 30. The support-substrate 30 may be divided into a first portion 72 and a second portion 74 on opposite sides of the crack. Since the device-substrate 10 may be fixed on the support-substrate 30 and be thinner than the support-substrate 30, the device-substrate 10 may be broken by the division of the support-substrate 30 along the crack 70. The device-substrate 10 may be broken in the same orientation as the support-substrate 30 on the crack 70.

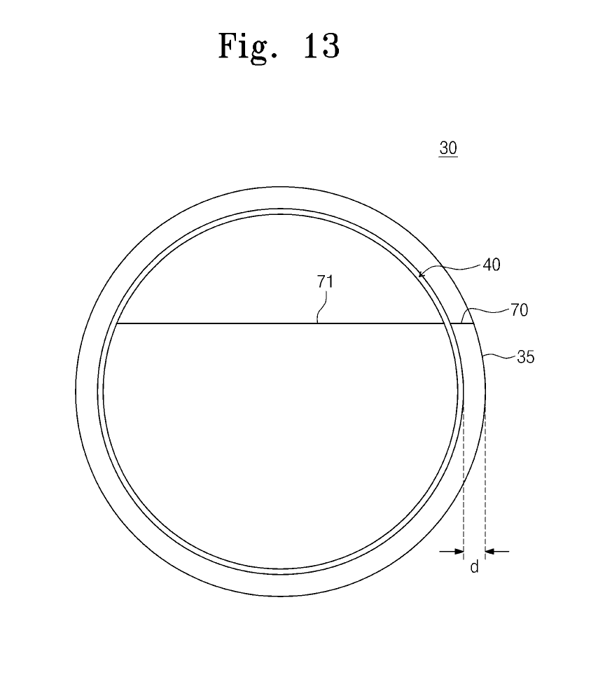

Referring to FIG. 13, according to the exemplary embodiments of the present general inventive concept, the grooved portion 40 may block a crack 70 in the support-substrate 30. The crack 70 may proceed from the second sidewall 35 to the grooved portion 40, which interrupts the crystal plane 71 and therefore prevents the crack 70 from propagating along the crystal plane 71. The grooved portion 40 may thus prevent the support-substrate 30 from being broken by the crack 70.

Thus, the method of treating the device-substrate according to exemplary embodiments of the present general inventive concept may prevent the device-substrate 10 from being broken by the crack 70 of the support-substrate 30.

The support-substrate 30 may be variously modified according to the shape of the grooved portion 40 and the shape of the second sidewall 35. These will be described herein.

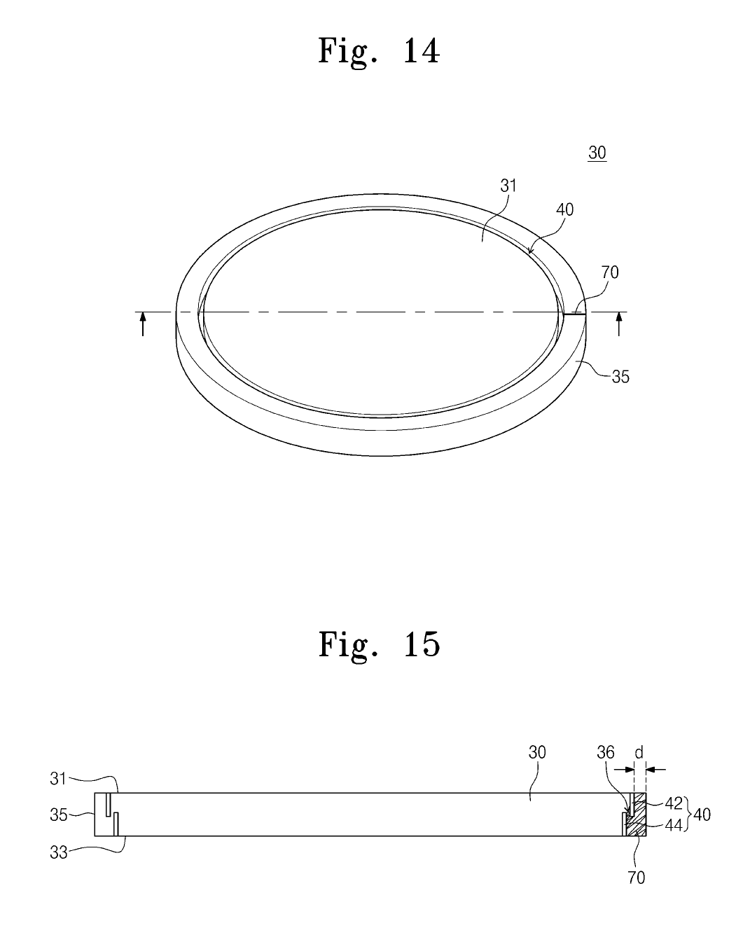

Referring to FIGS. 13 to 15, the support-substrate 30 according to a first exemplary embodiment may include at least one grooved portion 40 having a ring-shape in a plan view. The at least one grooved portion 40 having the ring-shape may be spaced apart from the second sidewall 35 by a distance d and extend along the second sidewall 35. The grooved portion 40 may be disposed at an edge of the support-substrate 30. The at least one grooved portion 40 may include a first groove 42 formed in the second top surface 31 and a second groove 44 formed in the second bottom surface 33. The first and second grooves 42 and 44 may have ring-shapes. The first and second grooves 42 and 44 may be spaced apart from each other. The first groove 42 may be spaced apart from the second sidewall 35 by a first distance, and the second groove 44 may be spaced apart from the second sidewall 35 by a second distance. The first distance may be greater or less than the second distance. A depth of the first groove 42 may be greater than a depth of the second groove 44. Each of depths of the first and second grooves 42 and 44 may be smaller than a thickness of the support-substrate 30. For example, if the support-substrate 30 has a thickness of about 7 mm, the first groove 42 and the second groove 44 may each have a depth of about 3.5 mm or more.

When the first and second grooves 42 and 44 are disposed at different distances from the second sidewall 35, a neck 36 is disposed between the first groove 42 and the second groove 44. If the crack 70 may occur from the second sidewall 35, the first and second grooves 42 and 44 may block the crack 70. The crack 70 may proceed between the second top surface 31 and the second bottom surface 33 from the second sidewall 35. The crack 70 may be blocked at the neck 36 between the first and second grooves 42 and 44.

Thus, it is possible to prevent the support-substrate 30 according to the first exemplary embodiment from being broken by the crack 70.

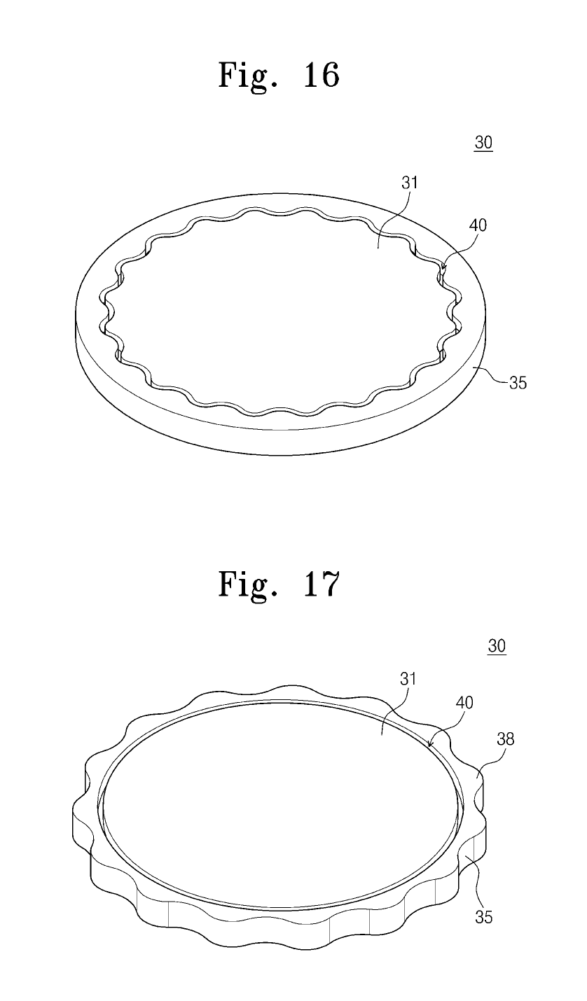

Referring to FIGS. 15 and 16, a support-substrate 30 according to a second exemplary embodiment may include a grooved portion 40 having a toothed wheel-shape in a plan view. The toothed wheel-shape may be that of a gear structure in a machine. The toothed wheel-shape may have saw-teeth arranged by equal intervals at a circumference thereof. The toothed wheel-shape may be a winding ring or a zigzag ring. Similarly to the first exemplary embodiment, the grooved portion 40 according to the second exemplary embodiment may include a first groove 42 formed from the second top surface of the support-substrate 30 and a second groove 44 formed from the second bottom surface of the support-substrate 30. One of the first groove 42 and second groove 44 of the grooved portion 40 according to the second exemplary embodiment may have the toothed wheel-shape and the other may have the ring-shape. For example, the first groove 42 may have the toothed wheel-shape and the second groove 44 may have ring-shape. Alternatively, the first groove 42 may have the ring-shape and the second groove 44 may have the toothed wheel-shape. The first groove 42 and second groove 44 of the grooved portion 40 according to the second exemplary embodiment may block the crack 70.

Thus, it is possible to prevent the support-substrate 30 according to the second exemplary embodiment from being broken by the crack 70.

Referring to FIG. 17, a support-substrate 30 according to a third exemplary embodiment may have a concave-convex part 38 formed at the sidewall 35 of the support-substrate 30. The concave-convex part 38 may reduce occurring probability of the crack at the sidewall 35 of the support-substrate 30. The substrate 30 may have the grooved portion 40 spaced apart from the sidewall 35 by distance d. Although FIG. 17 only illustrates the grooved portion 40 with a ring-shape, the grooved portion 40 may have the ring-shape and/or the toothed wheel-shape. If the crack may occur at the sidewall 35 having the concave-convex part 38, the grooved portion 40 may prevent the support-substrate 30 from being broken.

Thus, it is possible to prevent the support-substrate 30 according to the third exemplary embodiment from being broken by the crack 70.

According to exemplary embodiments of the present general inventive concept, the support-substrate 30 may fix the device-substrate 10 by the adhesive layer 20. The support-substrate 30 may include the second top surface 31, the second bottom surface 33 opposite to the second top surface 31, and the second sidewall 35 connecting the second top and bottom surfaces 31 and 33. The support-substrate 30 may include the grooved portion 40 spaced apart from the second sidewall 35 by distance d and formed at the top surface and/or the bottom surface thereof. The groove may block the crack 70 occurring from the second sidewall 35 of the support-substrate 30. Thus, it is possible to prevent the support-substrate 30 from being broken by the crack 70. As a result, breakage of the device-substrate 10 may be prevented.

While the present general inventive concept has been described with reference to example embodiments, it will be apparent to those skilled in the art that various changes and modifications may be made without departing from the spirit and scope of the present general inventive concept. Therefore, it should be understood that the above exemplary embodiments are not limiting, but illustrative. Thus, the scope of the present general inventive concept is to be determined by the broadest permissible interpretation of the following claims and their equivalents, and shall not be restricted or limited by the foregoing description.

1. A method of treating a device-substrate, comprising:
providing the device-substrate having an integrated circuit;
bonding a first top surface of the device-substrate to a support-substrate; and
polishing a first bottom surface of the device-substrate,
wherein the support-substrate includes a second top surface, a second bottom surface opposite to the second top surface, and a sidewall connecting the second top and bottom surfaces; and
wherein the support-substrate includes a grooved portion spaced apart from the sidewall and blocking a crack occurring from the sidewall.

2. The method of claim 1, wherein the grooved portion includes a first groove formed in the second top surface and a second groove formed in the second bottom surface; and
wherein the second groove is spaced apart from the first groove.

3. The method of claim 2, wherein a depth of the first groove is greater than a depth of the second groove.

4. The method of claim 1, wherein an area of the first top surface of the device-substrate is substantially equal to an area of the second top surface of the support-substrate.

5. The method of claim 1, wherein the grooved portion has a ring-shape in a plan view.

6. The method of claim 1, wherein the grooved portion has a toothed wheel-shape in a plan view.

7. The method of claim 1, wherein the sidewall of the support-substrate has a concave-convex part.

8. The method of claim 1, further comprising:
forming a via-hole in the device-substrate extending from the first top surface toward the first bottom surface of the device-substrate; and
forming a via-electrode in the via-hole.

9. The method of claim 8, further comprising:
after polishing the first bottom surface, etching the polished first bottom surface to expose the via-electrode.

10.-15. (canceled)

16. The method of claim 1, wherein an area of the first bottom surface of the device-substrate is less than an area of the first top surface of the device-substrate.

17. The method of claim 2, wherein the first and second grooves have different shapes.

18. A method of treating a device-substrate, comprising:
providing a support-substrate having a grooved portion, the grooved portion being configured to block a crack in the support-substrate occurring from a sidewall of the support-substrate;
bonding the support-substrate to a first surface of the device-substrate; and
polishing a second surface of the device-substrate, the second surface being opposite to the first surface.

19. (canceled)
